(19) United States
(12) Patent Application Publication
(10) Pub. No.: US 2025/0212554 A1
(43) Pub. Date: Jun. 26, 2025

(54) TRANSFER OF MULTIPLE SMALL ELEMENTS TO A CARRIER

(71) Applicant: ADEIA SEMICONDUCTOR BONDING TECHNOLOGIES INC., San Jose, CA (US)

(72) Inventors: Rajesh Katkar, Milpitas, CA (US); Belgacem Haba, Saratoga, CA (US); Cyprian Emeka Uzoh, San Jose, CA (US); Guilian Gao, Campbell, CA (US); Thomas Workman, San Jose, CA (US)

(21) Appl. No.: 18/745,374

(22) Filed: Jun. 17, 2024

Related U.S. Application Data
(60) Provisional application No. 63/614,241, filed on Dec. 22, 2023.

(51) Int. Cl. H01L 33/00

(52) U.S. Cl. CPC H10H 20/01; H10H 20/018; H10H 20/0362; H10H 20/0364

(57) ABSTRACT

A method of transferring a plurality of individual elements including providing a plurality of singulated elements on a stretchable tape, stretching the stretchable tape to increase separation between the singulated elements and forming a reconstituted wafer with at least one of the plurality of elements.

### BACKGROUND

### Field

The field relates to the transfer of multiple small elements to a carrier, for example, to micro light emitting diode (LED) displays and integrated visible/shortwave infrared sensors.

### Description of the Related Art

Fabrication of many electronic devices, for example but not limited to optical devices such as microLED displays and visible/SWIR sensors, may include a step of moving singulated electronic elements/dies from a first tape or substrate to a second substrate/carrier in which the distance between adjacent singulated dies on the first tape or substrate is different than the distance between adjacent singulated dies on the second substrate/carrier. For example, MicroLED displays are fabricated using heterogeneous pixel integration in which singulated LEDs from separate red (R), green (G) and blue (B) wafers are integrated on a carrier wafer to form a composite RGB pixel for the display. Similarly, integrated visible/shortwave infrared (SWIR) sensors may be fabricated by integrating singulated visible and/or SWIR elements on a carrier wafer to form composite pixels. Alternatively, singulated SWIR elements may be integrated into a silicon carrier wafer having visible sensors formed thereon. Conventional methods for the fabrication of microLED displays and integrated visible/shortwave infrared (SWIR) sensors use a pick and place technique in which singulated known good LED/SWIR elements are individually selected and placed on a substrate to form the pixels. This process tends to be slow and relatively expensive as each of the transferred elements are individually placed on the carrier.

Accordingly, it would be desirable to provide methods for fabricating integrated devices in which individual elements are transported from a first substrate or carrier to a second substrate or carrier (including, but not limited to, e.g., microLED displays and integrated visible/shortwave infrared (SWIR) sensors which overcomes the shortcomings of the convention processes.

### BRIEF DESCRIPTION OF THE DRAWINGS

Specific implementations will now be described with reference to the following drawings, which are provided by way of example, and not limitation.

FIG. 1A-1C illustrates a process flow diagram of a conventional method of making a microLED display.

FIG. 2 illustrates a four pixel portion of a microLED display fabricated according to some embodiments.

FIG. 3 illustrates an integrated visible/shortwave infrared (SWIR) sensor device fabricated according to some embodiments.

FIGS. 4A-4C illustrates a process flow diagram for fabricating an electronic device according to an embodiment.

FIGS. 5A-5D illustrates a process flow diagram for fabricating an electronic device according to another embodiment.

FIGS. 6A-6E illustrates a process flow diagram for fabricating an electronic device according to another embodiment.

FIGS. 7A-7E illustrates a process flow diagram for fabricating an electronic device according to another embodiment.

FIGS. 8A-8C illustrates a process flow diagram for fabricating an electronic device according to another embodiment.

FIGS. 9A-9D illustrates a process flow diagram for fabricating an electronic device according to another embodiment.

FIGS. 10A-10D illustrates a process flow diagram for fabricating an electronic device according to another embodiment.

FIGS. 11A-11G illustrates a process flow diagram for fabricating an electronic device according to another embodiment.

FIGS. 12A-12F illustrates a process flow diagram for fabricating an electronic device according to another embodiment.

FIGS. 13A-13E illustrates a process flow diagram for fabricating an electronic device according to another embodiment.

FIGS. 14A-14B schematically illustrate a process for forming a directly hybrid bonded structure without an intervening adhesive according to some embodiments.

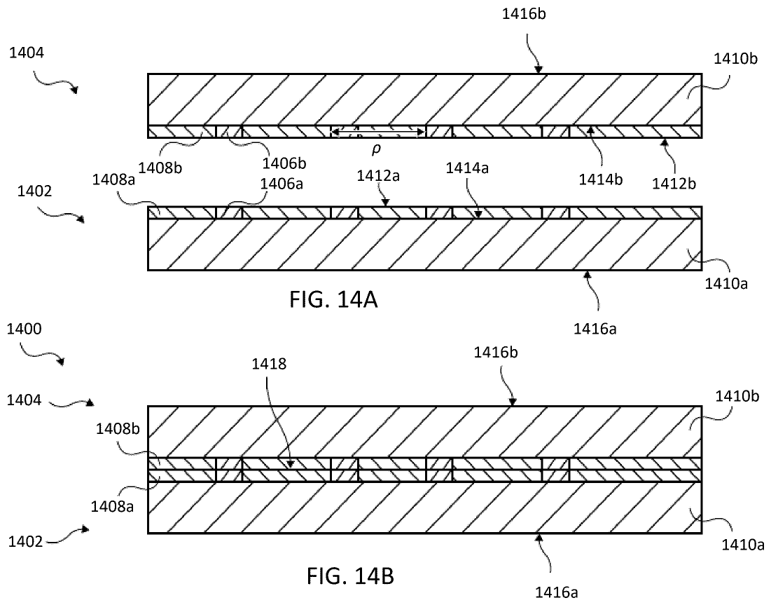

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

Several types of electronic devices, such as but not limited to optical elements, are fabricated using a transfer of individual electronic elements or elements to a separate carrier. Optical elements may include, for example, display elements such as microLED displays and sensor elements such as SWIR sensors. The individual electronic elements are typically located on a tape or wafer having a first spacing between the individual electronic elements, while the carrier has a second spacing between the individual electronic elements, where the second spacing is different from the first spacing. Thus, when transferring the individual electronic elements from the tape or wafer to the carrier, the spacing between individual electronic elements is changed. However, as discussed above, the conventional pick and place technique for transferring individual electronic elements from the tape or wafer to the carrier tends to be slow and relatively expensive as each of the individual electronic elements are individually transferred from the tape or wafer to the carrier.

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 1408a and/or 1408b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH2 molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

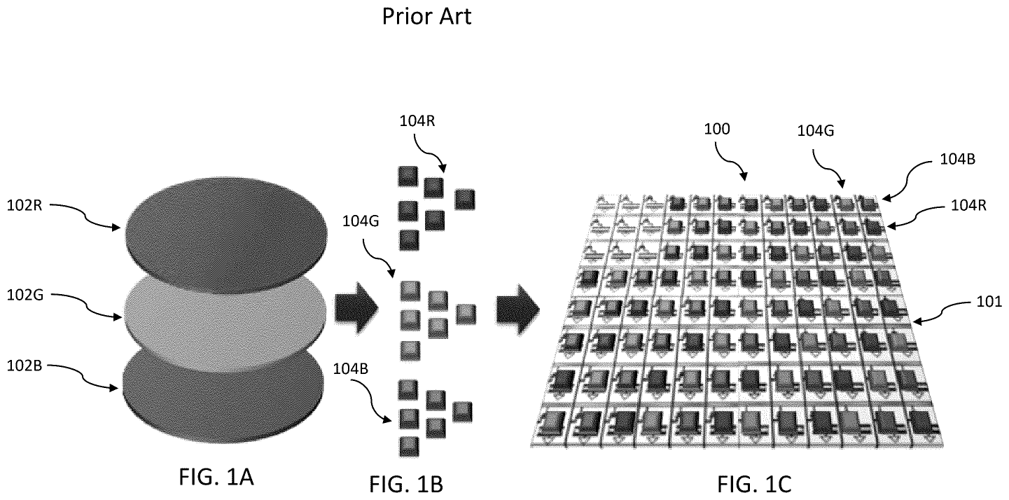

FIGS. 1A and 1B schematically illustrate cross-sectional side views of first and second elements 1402, 1404 prior to and after, respectively, a process for forming a directly bonded structure, and more particularly a hybrid bonded structure, according to some embodiments. In FIG. 1B, a bonded structure 1400 comprises the first and second elements 1402 and 1404 that are directly bonded to one another at a bond interface 1418 without an intervening adhesive. Conductive features 1406a of a first element 1402 may be electrically connected to corresponding conductive features 1406b of a second element 1404. In the illustrated hybrid bonded structure 1400, the conductive features 1406a are directly bonded to the corresponding conductive features 1406b without intervening solder or conductive adhesive.

The conductive features 1406a and 1406b of the illustrated embodiment are embedded in, and can be considered part of, a first bonding layer 1408a of the first element 1402 and a second bonding layer 1408b of the second element 1404, respectively. Field regions of the bonding layers 1408a, 1408b extend between and partially or fully surround the conductive features 1406a, 1406b. The bonding layers 1408a, 1408b can comprise layers of non-conductive materials suitable for direct bonding, as described above, and the field regions are directly bonded to one another without an adhesive. The non-conductive bonding layers 1408a, 1408b can be disposed on respective front sides 1414a, 1414b of base substrate portions 1410a, 1410b.

The first and second elements 1402, 1404 can comprise microelectronic elements, such as semiconductor elements, including, for example, integrated device elements, wafers, passive devices, discrete active devices such as power switches, MEMS, etc. In some embodiments, the base substrate portion can comprise a device portion, such as a bulk semiconductor (e.g., silicon) portion of the elements 1402, 1404, and back-end-of-line (BEOL) interconnect layers over such semiconductor portions. The bonding layers 1408a, 1408b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 1410a, 1410b, and can electrically communicate with at least some of the conductive features 1406a, 1406b. Active devices and/or circuitry can be disposed at or near the front sides 1414a, 1414b of the base substrate portions 1410a, 1410b, and/or at or near opposite backsides 1416a, 1416b of the base substrate portions 1410a, 1410b. In other embodiments, the base substrate portions 1410a, 1410b may not include active circuitry, but may instead comprise dummy substrates, passive interposers, passive optical elements (e.g., glass substrates, gratings, lenses), etc. The bonding layers 1408a, 1408b are shown as being provided on the front sides of the elements, but similar bonding layers can be additionally or alternatively provided on the back sides of the elements.

In some embodiments, the base substrate portions 1410a, 1410b can have significantly different coefficients of thermal expansion (CTEs), and bonding elements that include such different based substrate portions can form a heterogenous bonded structure. The CTE difference between the base substrate portions 1410a and 1410b, and particularly between bulk semiconductor (typically single crystal) portions of the base substrate portions 1410a, 1410b, can be greater than 5 ppm/° C. or greater than 10 ppm/° C. For example, the CTE difference between the base substrate portions 1410a and 1410b can be in a range of 5 ppm/° C. to 1400 ppm/° C., 5 ppm/° C. to 40 ppm/° C., 10 ppm/° C. to 1400 ppm/° C., or 10 ppm/° C. to 40 ppm/° C.

In some embodiments, one of the base substrate portions 1410a, 1410b can comprise optoelectronic single crystal materials, including perovskite materials, that are useful for optical piezoelectric or pyroelectric applications, and the other of the base substrate portions 1410a, 1410b comprises a more conventional substrate material. For example, one of the base substrate portions 1410a, 1410b comprises lithium tantalate (LiTaO3) or lithium niobate (LiNbO3), and the other one of the base substrate portions 1410a, 1410b comprises silicon (Si), quartz, fused silica glass, sapphire, or a glass. In other embodiments, one of the base substrate portions 1410a, 1410b comprises a III-V single semiconductor material, such as gallium arsenide (GaAs) or gallium nitride (GaN), and the other one of the base substrate portions 1410a, 1410b can comprise a non-III-V semiconductor material, such as silicon (Si), or can comprise other materials with similar CTE, such as quartz, fused silica glass, sapphire, or a glass. In still other embodiments, one of the base substrate portions 1410a, 1410b comprises a semiconductor material and the other of the base substrate portions 1410a, 1410b comprises a packaging material, such as a glass, organic or ceramic substrate.

In some arrangements, the first element 1402 can comprise a singulated element, such as a singulated integrated device die. In other arrangements, the first element 1402 can comprise a carrier or substrate (e.g., a semiconductor wafer) that includes a plurality (e.g., tens, hundreds, or more) of device regions that, when singulated, forms a plurality of integrated device elements, though in other embodiments such a carrier can be a package substrate or a passive or active interposer. Similarly, the second element 1404 can comprise a singulated element, such as a singulated integrated device die. In other arrangements, the second element 1404 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 1402, 1404 are shown, any suitable number of elements can be stacked in the bonded structure 1400. For example, a third element (not shown) can be stacked on the second element 1404, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 1402. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 1408a, 1408b, the bonding layers 1408a, 1408b can be prepared for direct bonding. Non-conductive bonding surfaces 1412a, 1412b at the upper or exterior surfaces of the bonding layers 1408a, 1408b can be prepared for direct bonding by polishing, for example, by chemical mechanical polishing (CMP). The roughness of the polished bonding surfaces 1412a, 1412b can be less than 30 Å rms. For example, the roughness of the bonding surfaces 1412a and 1412b can be in a range of about 0.1 Å rms to 15 Å rms, 0.5 Å rms to 10 Å rms, or 1 Å rms to 5 Årms. Polishing can also be tuned to leave the conductive features 1406a, 1406b recessed relative to the field regions of the bonding layers 1408a, 1408b.

Preparation for direct bonding can also include cleaning and exposing one or both of the bonding surfaces 1412a, 1412b to a plasma and/or etchants to activate at least one of the surfaces 1412a, 1412b. In some embodiments, one or both of the surfaces 1412a, 1412b can be terminated with a species after activation or during activation (e.g., during the plasma and/or etch processes). Without being limited by theory, in some embodiments, the activation process can be performed to break chemical bonds at the bonding surface(s) 1412a, 1412b, and the termination process can provide additional chemical species at the bonding surface(s) 1412a, 1412b that alters the chemical bond and/or improves the bonding energy during direct bonding. In some embodiments, the activation and termination are provided in the same step, e.g., a plasma to activate and terminate the surface(s) 1412a, 1412b. In other embodiments, one or both of the bonding surfaces 1412a, 1412b can be terminated in a separate treatment to provide the additional species for direct bonding. In various embodiments, the terminating species can comprise nitrogen. For example, in some embodiments, the bonding surface(s) 1412a, 1412b can be exposed to a nitrogen-containing plasma. Other terminating species can be suitable for improving bonding energy, depending upon the materials of the bonding surfaces 1412a, 1412b. Further, in some embodiments, the bonding surface(s) 1412a, 1412b can be exposed to fluorine. For example, there may be one or multiple fluorine concentration peaks at or near a bond interface 1418 between the first and second elements 1402, 1404. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and U.S. Pat. No. 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 1400, the bond interface 1418 between two non-conductive materials (e.g., the bonding layers 1408a, 1408b) can comprise a very smooth interface with higher nitrogen (or other terminating species) content and/or fluorine concentration peaks at the bond interface 1418. In some embodiments, the nitrogen and/or fluorine concentration peaks may be detected using various types of inspection techniques, such as SIMS techniques. The polished bonding surfaces 1412a and 1412b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 1408a and 1408b can be directly bonded to one another without an adhesive. In some embodiments, the elements 1402, 1404 are brought together at room temperature, without the need for application of a voltage, and without the need for application of external pressure or force beyond that used to initiate contact between the two elements 1402, 1404. Contact alone can cause direct bonding between the non-conductive surfaces of the bonding layers 1408a, 1408b (e.g., covalent dielectric bonding). Subsequent annealing of the bonded structure 1400 can cause the conductive features 1406a, 1406b to directly bond.

In some embodiments, prior to direct bonding, the conductive features 1406a, 1406b are recessed relative to the surrounding field regions, such that a total gap between opposing contacts after dielectric bonding and prior to anneal is less than 15 nm, or less than 10 nm. Because the recess depths for the conductive features 1406a and 1406b can vary across each element, due to process variation, the noted gap can represent a maximum or an average gap between corresponding conductive features 1406a, 1406b of two joined elements (prior to anneal). Upon annealing, the conductive features 1406a and 1406b can expand and contact one another to form a metal-to-metal direct bond.

During annealing, the conductive features 1406a, 1406b (e.g., metallic material) can expand while the direct bonds between surrounding non-conductive materials of the bonding layers 1408a, 1408b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 1406a, 1406b can comprise discrete pads, contacts, electrodes, or traces at least partially embedded in the non-conductive field regions of the bonding layers 1408a, 1408b. In some embodiments, the conductive features 1406a, 1406b can comprise exposed contact surfaces of TSVs (e.g., through silicon vias).

As noted above, in some embodiments, in the elements 1402, 1404 of FIG. 1A prior to direct bonding, portions of the respective conductive features 1406a and 1406b can be recessed below the non-conductive bonding surfaces 1412a and 1412b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 1406a, 1406b or to average depths of the recesses relative to local non-conductive field regions. Even for an individual conductive feature 1406a, 1406b, the vertical recess can vary across the feature, and so can be measured at or near the lateral middle or center of the cavity in which a given conductive feature 1406a, 1406b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 1406a, 1406b across the direct bond interface 1418 (e.g., small or fine pitches for regular arrays).

In some embodiments, a pitch p of the conductive features 1406a, 1406b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 1406a and 1406b to one of the lateral dimensions (e.g., a diameter) of the bonding pad is less than is less than 20, or less than 10, or less than 5, or less than 3 and sometimes desirably less than 2. In various embodiments, the conductive features 1406a and 1406b and/or traces can comprise copper or copper alloys, although other metals may be suitable, such as nickel, aluminum, or alloys thereof. The conductive features disclosed herein, such as the conductive features 1406a and 1406b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 1402, 1404, as shown, the orientations of one or more conductive features 1406a, 1406b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 1406b in the bonding layer 1408b (and/or at least one internal conductive feature, such as a BEOL feature) of the upper element 1404 may be tapered or narrowed upwardly, away from the bonding surface 1412b. By way of contrast, at least one conductive feature 1406a in the bonding layer 1408a (and/or at least one internal conductive feature, such as a BEOL feature) of the lower element 1402 may be tapered or narrowed downwardly, away from the bonding surface 1412a. Similarly, any bonding layers (not shown) on the backsides 1416a, 1416b of the elements 1402, 1404 may taper or narrow away from the backsides, with an opposite taper orientation relative to front side conductive features 1406a, 1406b of the same element.

As described above, in an anneal phase of hybrid bonding, the conductive features 1406a, 1406b can expand and contact one another to form a metal-to-metal direct bond. In some embodiments, the materials of the conductive features 1406a, 1406b of opposite elements 1402, 1404 can interdiffuse during the annealing process. In some embodiments, metal grains grow into each other across the bond interface 1418. In some embodiments, the metal is or includes copper, which can have grains oriented along the 111 crystal plane for improved copper diffusion across the bond interface 1418. In some embodiments, the conductive features 1406a and 1406b may include nanotwinned copper grain structure, which can aid in merging the conductive features during anneal. There is substantially no gap between the non-conductive bonding layers 1408a and 1408b at or near the bonded conductive features 1406a and 1406b. In some embodiments, a barrier layer may be provided under and/or laterally surrounding the conductive features 1406a and 1406b (e.g., which may include copper). In other embodiments, however, there may be no barrier layer under the conductive features 1406a and 1406b.

Uses for microLED, smart watches, automotive displays, cell phones, computer/laptop monitors, televisions, etc. As discussed in more detail below, pixel sizes of the microLED displays vary depending on the use of the displays.

SWIR sensors are commonly used in industrial and security/surveillance applications but have found new markets in mobile devices and in the automotive industry. Additional uses include applications in detecting counterfeiting, medical diagnostics, biometrics, pharmaceutical and agriculture. Unlike mediumwave infrared (MWIR) and longwave infrared (LWIR), from which light is emitted from the object itself, SWIR light is similar to visible light in that photons are reflected or absorbed by an object. This reflection/absorption provides strong contrast for high resolution imaging.

Many materials have specific reflectance and absorption features in the SWIR bands that allow for their characterization and use as sensors. For example, InGaAs has spectral response vary between 900-2600 nm which may be used for SWIR technology. The desired wavelength response may be tuned by adjusting InAs and GaAs percentage ratios. Other traditional small bandgap materials which may be used for IR/SWIR include PbSe, InSb, and Hg₁₋ₓCdₓTe, etc.

For high volume consumer and automotive applications using visible and SWIR wavelengths, multiple cameras are generally deployed with different optical paths and optics. While one camera with optical sensor crates an optical image, another camera with IR or SWIR sensor and separate optical path and lens system creates the image corresponding to its spectral band. The images are then digitally merged to create combined image. This may be both challenging and expensive. Further, the fact that typical complementary metal oxide semiconductor (CMOS) pixels are generally smaller (˜1-5 μm) versus typical SWIR/InGaAs pixels (10-40 μm) further complicates the data merging between the two captured images at the pixel level.

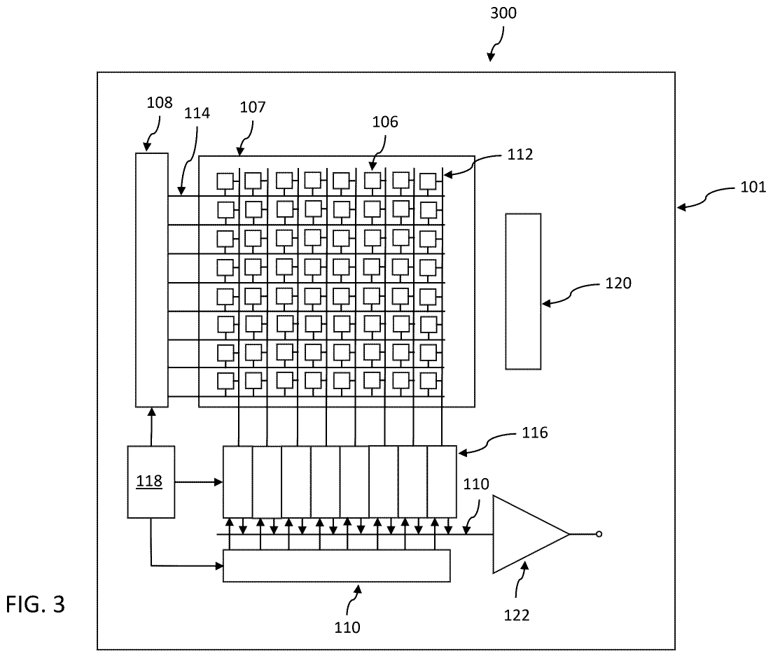

As discussed above, electronic devices, such as optical elements, including but not limited to microLED displays and integrated visible/SWIR sensors are typically assembled using a pick and place method. FIGS. 1A-1C illustrates a conventional method of fabricating a microLED display. However, the methods described herein are applicable to many other electronic devices, including optical elements such as sensors. In FIG. 1A, individual red wafers 102R, blue wafers 102B and green wafers 102G of LEDs are first formed. That is, the individual red wafers 102R include LEDs configured to emit red light, the individual blue wafers 102B include LEDs configured to emit blue light and the individual green wafers 102G include LEDs configured to emit green light. The individual red wafers 102R, blue wafers 102B and green wafers 102G are then diced to form individual red singulated elements 104R, green singulated elements 104G and blue singulated elements 104B as illustrated in FIG. 1B. As illustrated in FIG. 1C, the individual red singulated elements 104R, green singulated elements 104G and blue singulated elements 104B are individually placed on a substrate/carrier 101 (e.g. Silicon or TFT backplane) to form the integrated microLED display 100. The singulated elements 104R, 104G and 104B constitute a single colored pixel. Shown in more detail in FIG. 3 and described in more detail below, the substrate/carrier 101 may include other components. For example, the substrate/carrier 101 may include a vertical drive circuit 108, column signal processing circuits 116, a horizontal drive circuit 110, an output circuit 122, and a control circuit 118. In addition, the substrate/carrier 101 may include other components as desired. In an embodiment, each pixel 106 may have its own dedicated processor. In other embodiments, a single processor may control several pixels 106 or even all of the pixels 106.

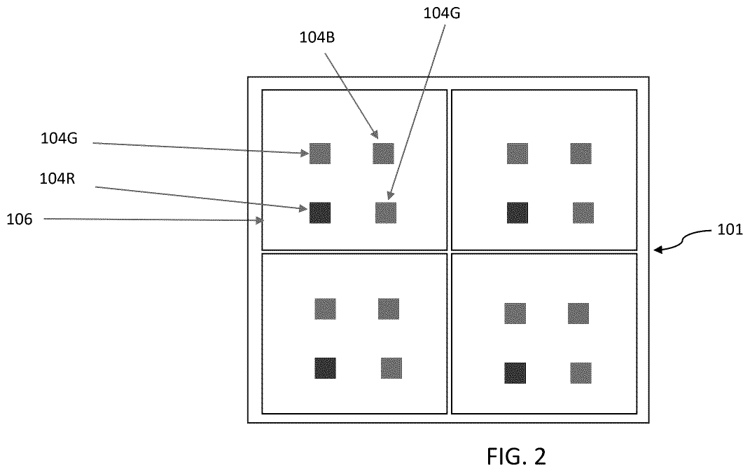

FIG. 2 illustrates a four pixel 106 portion of a microLED display 100. Also shown is a portion of the substrate/carrier 101 upon which the red, green and blue singulated elements 104R, 104G, 104B are mounted. As illustrated the size of the pixel 106 is generally larger than the size of the individual red singulated elements 104R, green singulated elements 104G and blue singulated elements 104B. As illustrated, each pixel includes one red singulated die 104R, two singulated green elements 104G and one blue singulated die 104B. Pixels with other combination of singulated elements may be formed. The size of the pixel 106 for a display varies depending on the type of display. For example, an augmented reality/virtual reality AR/VR display may have a pixel size less than 5 um. Cell phones may have a pixel 106 size on the order of about 50 um. Computer monitors may have a pixel 106 size on the order of about 350 um. The size of the pixels 106 for televisions may be greater than 0.5 mm. The ratio of the size (e.g., area) of the pixel 106 to the LED size (e.g., area) may vary from about 1.5-3 in AR/VR applications to greater than 100 in televisions. Further, the control circuit for the microLED display 100 may be shared by several pixels 106, therefore small silicon real estate on the carrier wafer is acceptable.

FIG. 3 illustrates an integrated visible/SWIR sensor 300. In an embodiment, the visible/SWIR sensor 300 may include sensors configured to detect visible light and sensors configured to detect short wave infrared light. In other embodiments, the visible/SWIR sensor 300 may include only sensors configured to detect visible light or sensors configured to detect short wave infrared light The embodiment visible/SWIR sensor device 300 in FIG. 3 includes: a pixel array region 107 in which pixels 106 are arranged in a two-dimensional matrix on a semiconductor substrate 101, i.e. silicon backplane or thin film transistor (TFT), using for example, single crystal silicon (Si) as a semiconductor. In other embodiments, the substrate 101 may be made of semiconductor materials other than silicon, including compound semiconductors such as III-V and II-VI compound semiconductors. Around the periphery of the pixel array region 107 is peripheral circuit region. The peripheral circuit region includes a vertical drive circuit 108, column signal processing circuits 116, a horizontal drive circuit 110, an output circuit 122, and a control circuit 118. The peripheral circuit region also includes an input/output terminal 120.

The pixels 106 may include individual visible/SWIR sensor elements (not shown). Although not shown in FIGS. 1 and 2, the microLED device 100 discussed above may also have the various peripheral circuits discussed in regards to the visible/SWIR sensor device 300.

The control circuit 118 may receive input clock data and instructions on an operation mode and provide output data such as internal information of the visible/SWIR sensor device 300. That is, the control circuit 118 may generate a clock signal and a control signal serving as references for operations of the vertical drive circuit 108, the column signal processing circuit 116, the horizontal drive circuit 110, and the like based on a vertical synchronization signal, a horizontal synchronization signal, and a master clock. Then, the control circuit 118 may output the generated clock signal and control signal to the vertical drive circuit 108, the column signal processing circuit 116, the horizontal drive circuit 110, etc.

The vertical drive circuit 108 may include, for example, a shift register. The vertical drive circuit 108 may select a predetermined horizontal signal line 114, supply a pulse for driving the pixel 102 to the selected horizontal signal line 114, and drive the pixels 106 in units of rows.

That is, the vertical drive circuit 108 selectively scans the pixels 106 in the pixel array region 107 sequentially in the vertical direction in units of rows. Then, the vertical drive circuit 108 supplies a pixel signal based on a signal charge generated according to the amount of received light in the photoelectric conversion unit of each of the pixels 106 to the column signal processing circuit 116 through a vertical signal line 112.

The column signal processing circuit 116 is arranged for each column of the pixels 106, and may perform signal processing, such as noise removal, on signals output from the pixels 106 of one row for each column.

The horizontal drive circuit 110 includes, for example, a shift register, and sequentially outputs horizontal scanning pulses to sequentially select each of the column signal processing circuits 116 such that a pixel signal is output from each of the column signal processing circuits 116 to a horizontal signal line 114.

The output circuit 122 performs signal processing on the signals sequentially supplied from the column signal processing circuits 116 through the horizontal signal line 114 and outputs the processed signals. For example, the output circuit 122 may perform only buffering, or may perform black level adjustment, column variation correction, various types of digital signal processing, etc. An input/output terminal 120 exchanges signals with external devices or controllers.

As discussed above, and illustrated in FIGS. 1 and 2, the fabrication for several types of electronic devices includes moving singulated electronic elements from a first tape or substrate to a second substrate/carrier. Often, the distance between adjacent singulated elements on the first tape or substrate is different than the distance between adjacent singulated elements on the second substrate/carrier. In this case, the electronic devices are fabricated using a pick and place in which individual elements are taken from the first tape or substrate and placed on the second substrate/carrier one at a time. For microdisplays with a resolution of, for example 4 MP, would involve singulating 4 million of red, green and blue dies/pixels respectively from red, green and blue wafers, picking them from their respective singulation tapes/carrier and transferring these total 12 million pixels/dies to the silicon or TFT backplane or another intermediate carrier. This method of fabrication is cumbersome, slow and expensive. The embodiments below provide alternative methods of fabricating electronic devices in which multiple elements may be moved at the same time, thereby providing faster and less expensive methods of fabrication.

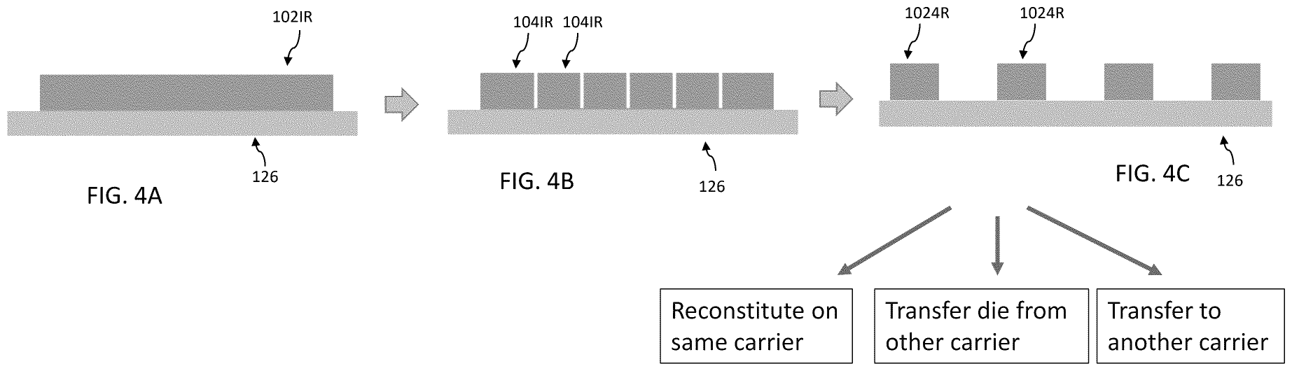

FIGS. 4A-4C illustrates a process flow diagram for fabricating an optical device such as a microLED display 100 or a visible/SWIR sensor 300 according to an embodiment. Note, the embodiment method described in FIGS. 4A-4C and the any of the embodiment methods described below are not limited to optical devices and may be used to make any type of electronic device in which singulated electronic elements/dies are moved from a first tape or substrate to a second substrate/carrier (not shown). As illustrated in FIG. 4A of this embodiment, a wafer, such as an infrared wafer 102IR, is provided on a stretchable tape 126. The stretchable tape 126 may be made of any suitable material, such as an organic stretchable film, such as stretchable resin. Example materials include but are not limited to, ExxonMobil Enable™ 20-10HE Metallocene Polyethylene Resin, ExxonMobil Enable™ 20-05 Series, Metallocene Polyethylene Resin ExxonMobil Enable™ 20-10 Series Metallocene Polyethylene Resin, ExxonMobil Enable™ 35-05HH, Metallocene Polyethylene Resin, ExxonMobil Enable™ 3812CB, ExxonMobil Enable™ 7518CB, and Vistamaxx 3980FL™. The stretchable tape 126 may be affixed to a tape frame carrier (not shown) for support. As illustrated in FIG. 4B, the infrared wafer 102IR may be diced on the tape 126 to form individual singulated IR elements 104IR. In another embodiment, the wafer may diced on another carrier/support layer or a substrate and then transferred to a stretchable tape 126. Next, as illustrated in FIG. 4C, the stretchable tape 126 may be stretched to provide increased separation between the individual singulated IR elements 104IR. In some embodiments, the stretchable tape 126 may be stretched between 50% to 300% (e.g., to increase the tape's area from an unstretched area to a stretched area that is 50% to 300% larger than the unstretched area). As discussed above, the individual singulated IR elements 104IR may be made of any suitable type of semiconductor material, including, e.g., silicon or compound III-V semiconductors, such as GaAs, InAs, GaP, InP, PbSe, InSb, and Hg1−xCdxTe or ternary or quaternary combinations of Ga, In, Pb As, P and/or Se.

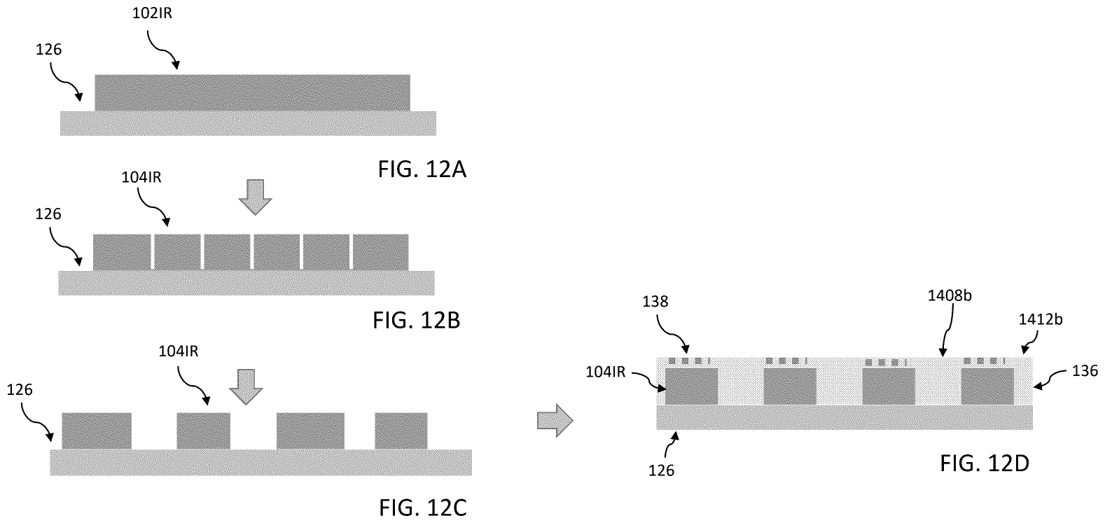

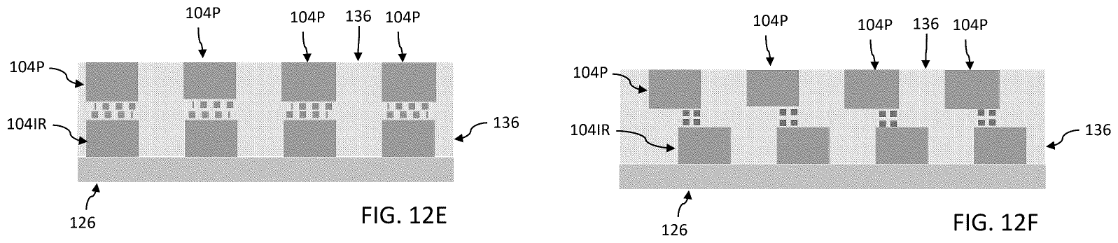

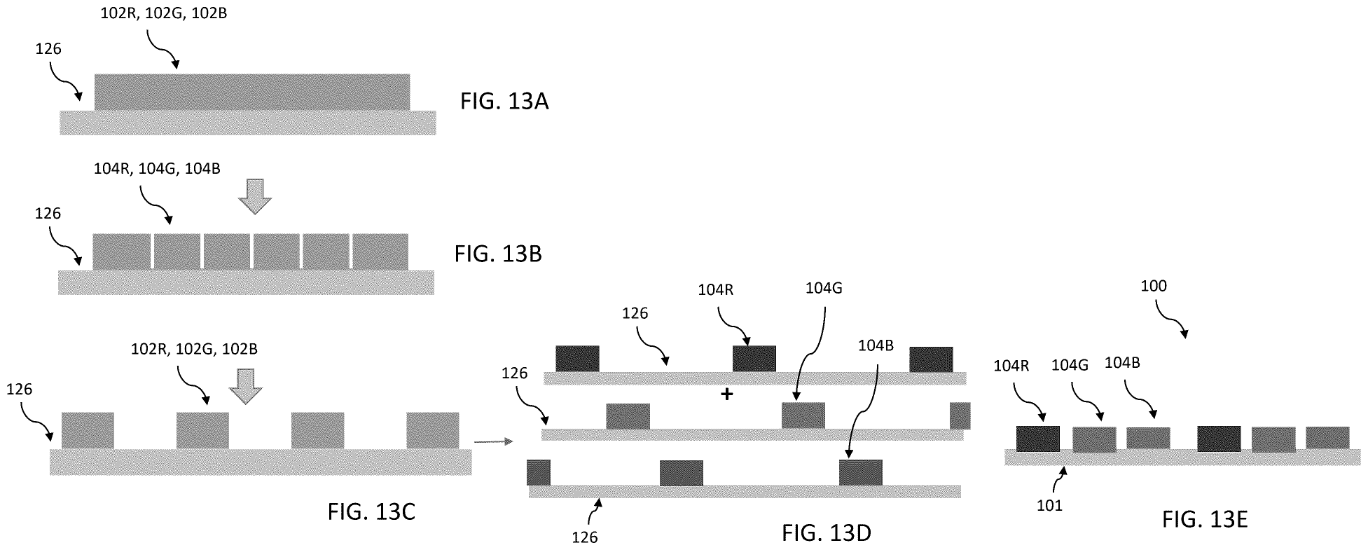

After stretching the stretchable tape 126, the individual singulated IR elements 104IR may be tested to determine known good dies (KGDs). After testing individual singulated IR elements/dies 104IR, the individual singulated IR elements 104IR may be reconstituted on the same carrier, known good elements transferred from another carrier to the current carrier or transferred from the current carrier to another carrier. Reconstituting may include applying an insulating encapsulant layer 136 (see FIG. 12D) over the elements/dies 104R, 104G, 104B, 104IR and the carrier/substrate 101 to which the elements/dies 104R, 104G, 104B, 104IR are ultimately mounted. The insulating encapsulant layer 136 may be an inorganic dielectric of one or multiple layers (e.g., silicon oxide, silicon nitride, silicon oxynitride, silicon carbonitride, etc.) or it may be an organic material, such as a resin, epoxy or a molding compound. Example, optical devices are illustrated in FIGS. 11A-13E and described in more detail below. The optical devices, such as microLED displays 100 and visible/SWIR sensor devise 300 illustrated in FIGS. 11G and 13E, may reconstituted as illustrated in FIG. 12D. That is the encapsulant layer 138 illustrated in FIG. 12D is deposited over the carrier wafer 101 and the elements/dies 104R, 104G, 104B, 104IR.

Although, not illustrated in FIGS. 4A-4C, in the various methods of the instant application, multiple elements/dies 104R, 104G, 104B, 104IR may be transferred at the same time from the stretchable tape 126 to the substrate/carrier 101 at the same time. This is because the step of stretching the stretchable tape 126 results in the elements/dies 104R, 104G, 104B, 104IR having the proper spacing for the substrate/carrier 101. In this manner, the method of making the electronic devices can be accomplished faster (i.e., by having fewer transfer steps), resulting in cheaper electronic devices. Further, the singulated IR elements 104IR (and the singulated red, green and blue elements/dies 104R, 104G, 104B in the microLED displays discussed below) may be direct hybrid bonded to the substrate, carrier. This is advantageous because direct hybrid bonding can achieve smaller pitches and avoids the problems associated with soldering.

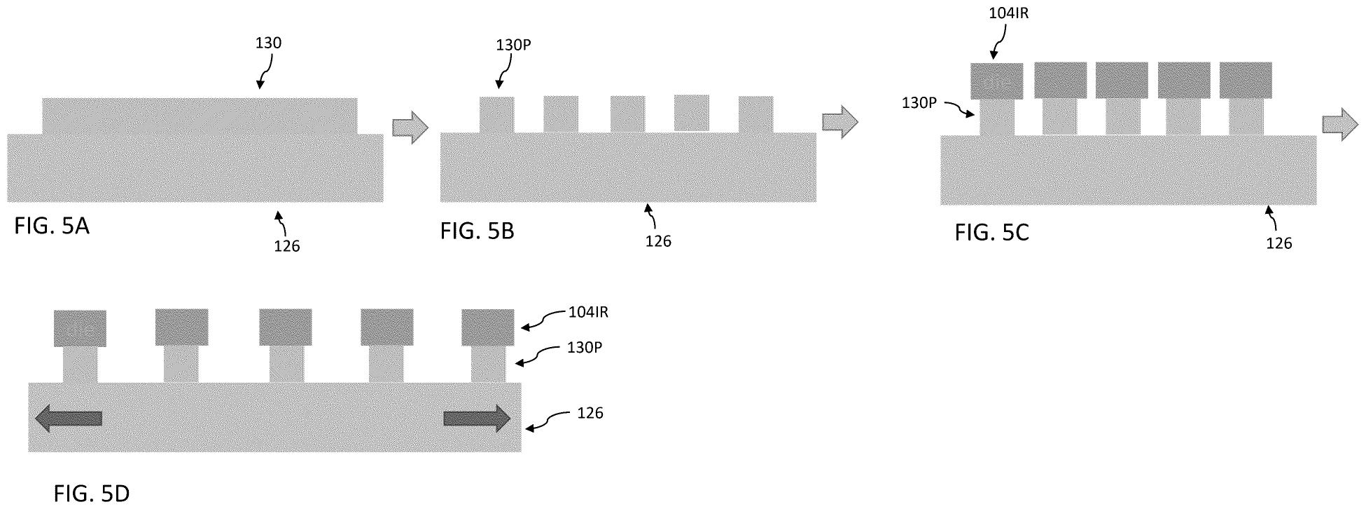

FIGS. 5A-5D illustrates a process flow diagram for fabricating an electronic device, such as an optical device, e.g. a microLED display 100 or a visible/SWIR sensor 300 according to another embodiment. As illustrated in FIG. 5A, a photo imageable adhesive 130 may be deposited on a stretchable tape 126. As in the embodiments above, the stretchable tape 126 may be mounted on a tape frame carrier (not shown). As illustrated in FIG. 5B, the photo imageable adhesive 130 may be patterned to form pillars of adhesive 130P. The photo imageable adhesive 130 may be a negative photo adhesive, in which those portions exposed to light become insoluble or a positive photo adhesive, in which those portions exposed to light become soluble.

As illustrated in FIG. 5C, individual singulated IR elements 104IR may be affixed to the pillars of adhesive 130P. In an embodiment, the individual singulated IR elements 104IR may be singulated prior to being affixed to the pillars of adhesive 130P. In an alternative embodiment, infrared wafer 102IR may be affixed to the pillars of adhesive 103P and then diced to form the individual singulated IR elements 104IR. As illustrated in FIG. 5D, the stretchable tape 126 may be stretched to increase the separation between the individual singulated IR elements 104IR. More specifically, the stretchable tape 126 is stretched such that separation between the individual singulated IR elements 104IR is suitable for transfer individual of multiple singulated IR elements 104IR to the substrate/carrier 101 in a single step.

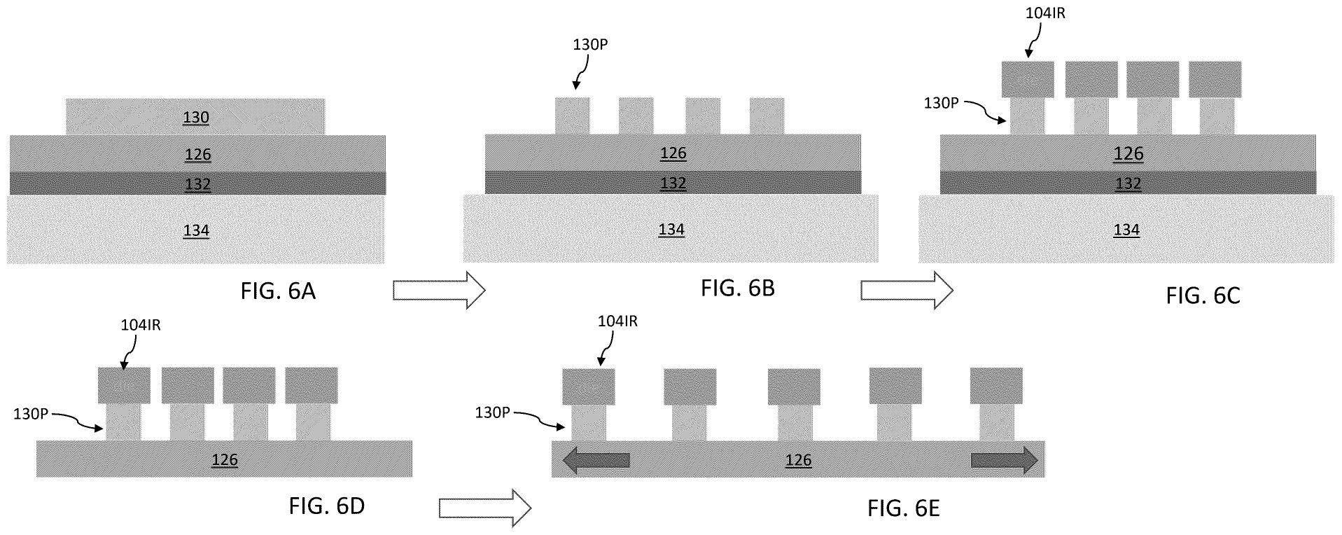

FIGS. 6A-6E illustrates a process flow diagram for fabricating an electronic device, such as an optical device, e.g. a microLED display 100 or a visible/SWIR sensor 300 according to another embodiment. As illustrated in FIG. 6A, a carrier 134, such as a glass carrier, is provided with a release film 132 located thereon. A stretchable tape 126 is provided on the release film 132, while a photo imageable adhesive 130 is provided on the stretchable tape 126. As illustrated in FIG. 6B, the photo imageable adhesive 130 may be patterned to form pillars of adhesive 130P. As illustrated in FIG. 6C, individual singulated IR elements 104IR may be affixed to the pillars of adhesive 130P. In an embodiment, the individual singulated IR elements 104IR may be singulated prior to being affixed to the pillars of adhesive 130P. In an embodiment, the wafer 102IR may be singulated on another carrier to form, the individual singulated IR elements 104IR prior to them being affixed to the pillars of adhesive 130P. In an alternative embodiment, an infrared wafer 102IR may be affixed to the pillars of adhesive 103P and then diced on the adhesive 130 and tape 126 to form the individual singulated IR elements 104IR.

As illustrated in FIG. 6D, the stretchable tape 126, pillars of adhesive 130P and individual singulated IR elements 104IR may be separated from the carrier 134 via the release film 132. In an embodiment, the release film may be dissolved with a solvent. In another embodiment, the intermediate structure illustrate in FIG. 6C is exposed to ultraviolet (UV) light or is heated to separate the stretchable tape 126 from the release film 132. As illustrated in FIG. 6E, the stretchable tape 126 may then be stretched to increase the separation between the individual singulated IR elements 104IR. As in the embodiments discussed above, the stretchable tape 126 is stretched such that separation between the individual singulated IR elements 104IR is suitable for transfer individual of multiple singulated IR elements 104IR to the substrate/carrier 101 in a single step.

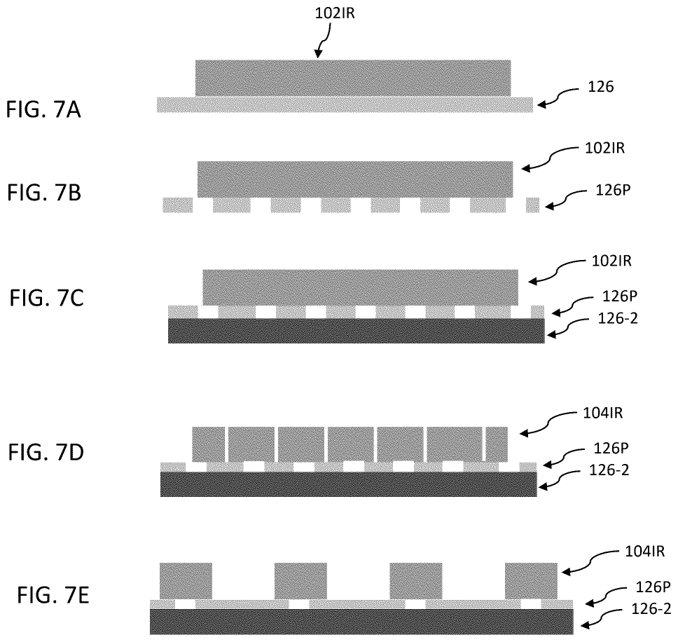

FIGS. 7A-7E illustrates a process flow diagram for fabricating an electronic device, such as an optical device, e.g. a microLED display 100 or visible/SWIR sensor 300 according to another embodiment. As illustrated in FIG. 7A, an infrared wafer 102IR may be provided on a first stretchable tape 126. As illustrated in FIG. 7B, the stretchable tape 126 may be patterned by laser direct writing lithography, or by photolithography. For example, A photo patternable stretchable film has been reported by Zhu, et al (see e.g., https://www.nature.com/articles/micronano20174, hereby incorporated by reference in its entirety) to form a patterned stretchable tape 126P. As illustrated in FIG. 7C, the patterned stretchable tape 126P may be attached to a second stretchable tape 126-2. Next, as illustrated in FIG. 7D, the infrared wafer 102IR may be diced while mounted to the tapes 126, 126-2 to form individual singulated IR elements 104IR. Then, as illustrated in FIG. 7E, the first stretchable tape 126 and the second stretchable tape 126-2 may be stretched to increase the separation between the individual singulated IR elements 104IR. The second stretchable tape 126-2 provides support for the first stretchable tape 126. Further, because the first stretchable tape 126 is patterned prior to being attached to a second stretchable tape 126-2, the spacing between the individual singulated IR elements 104IR can be made larger than if the second stretchable tape was not used.

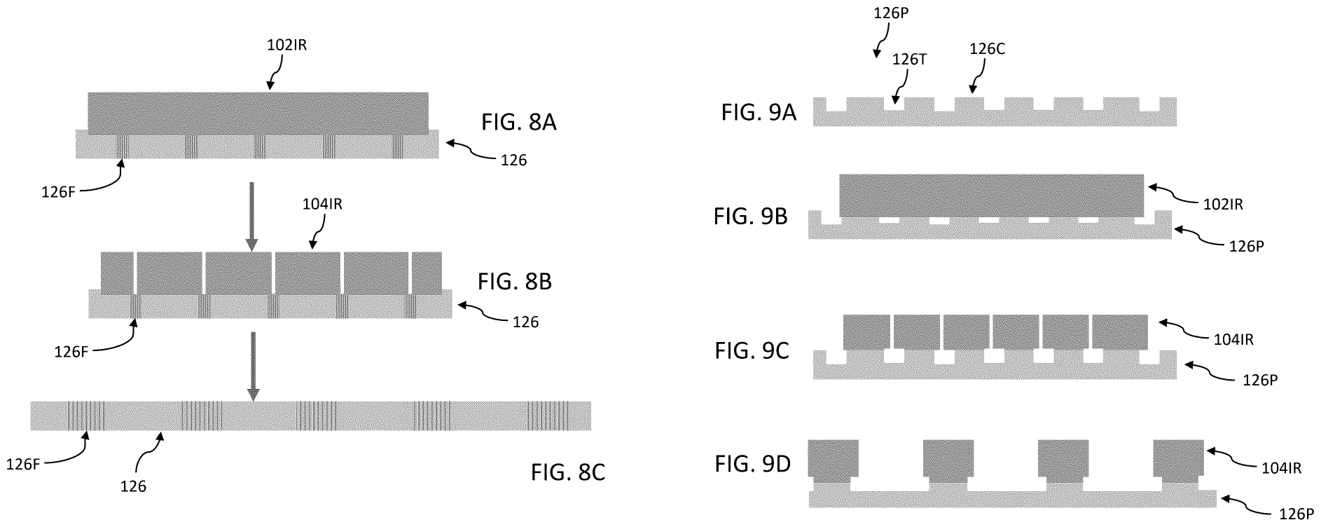

FIGS. 8A-8C illustrates a process flow diagram for fabricating an electronic device, such as an optical device, e.g. a microLED display 100 or visible/SWIR sensor 300 according to another embodiment. As illustrated in FIG. 8A of this embodiment, an infrared wafer 102IR is provided on a stretchable tape 126. However, in this embodiment, the stretchable tape 126 includes folded portions 126F. As illustrated in FIG. 8B, the infrared wafer 102IR may be diced to form individual singulated IR elements 104IR. Next, as illustrated in FIG. 8C the folded portion 126P of stretchable tape 126 may be opened, thereby stretching the stretchable tape 126 to an enlarged area. In this manner the separation between the individual singulated IR elements 104IR is suitable for transfer individual of multiple singulated IR elements 104IR to the substrate/carrier 101 in a single step.

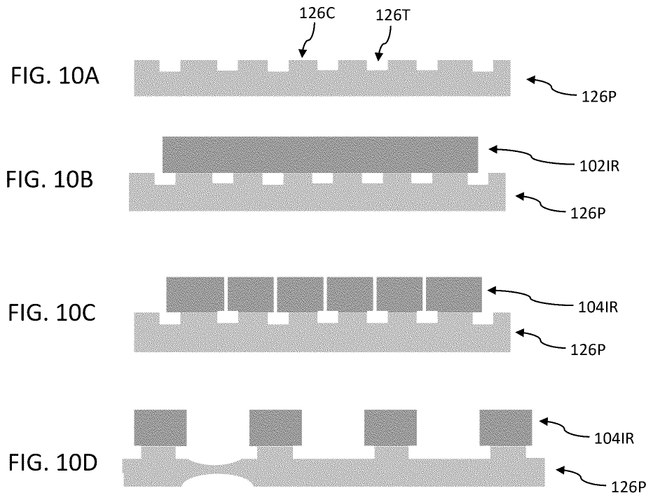

FIGS. 9A-9D illustrates a process flow diagram for fabricating an electronic device, such as an optical device, e.g. a microLED display 100 or visible/SWIR sensor 300 according to another embodiment. As illustrated in FIG. 9A, a patterned stretchable tape 126P is provided. The patterned stretchable tape 126P includes trenches 126T and columns 126C. Next, as illustrated in FIG. 9B, an infrared wafer 102IR is affixed to the columns 126C of the patterned stretchable tape 126P. Then, as illustrated in FIG. 9C, the infrared wafer 102IR may be diced to form individual singulated IR elements 104IR located on the columns 126C of the patterned stretchable tape 126P. Then, as illustrated in FIG. 9D, the patterned stretchable tape 126P may be stretched to provide increased separation between the individual singulated IR elements 104IR. In this manner the separation between the individual singulated IR elements 104IR is suitable for transfer individual of multiple singulated IR elements 104IR to the substrate/carrier 101 in a single step

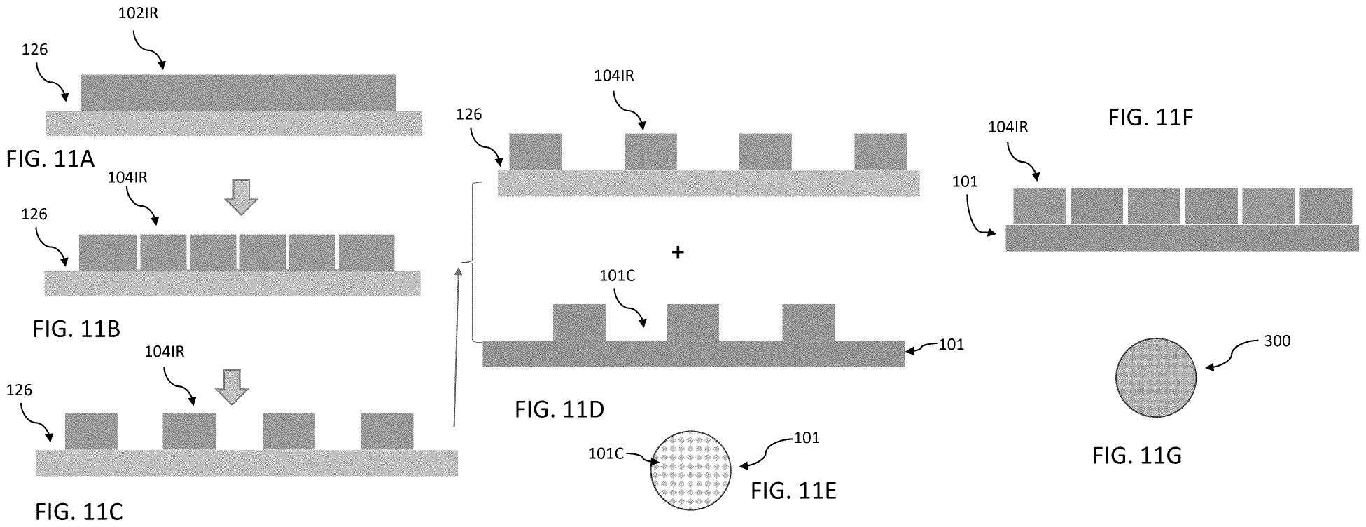

FIGS. 10A-10D illustrates a process flow diagram for fabricating an electronic device, such as an optical device, e.g. a microLED display 100 or a sensor device 300 according to another embodiment. As illustrated in FIG. 10A, a patterned stretchable tape 126P is provided. Next, as illustrated in FIG. 10B, an infrared wafer 102IR is affixed to the columns 126C of the patterned stretchable tape 126P. Then, as illustrated in FIG. 10C, the infrared wafer 102IR may be diced to form individual singulated IR elements 104IR. Next, as illustrated in FIG. 10D, the patterned stretchable tape 126P may be stretched to provide increased separation between the individual singulated IR elements 104IR. However, in contrast to the previous embodiment, the portions of the patterned stretchable tape 126P located between the individual singulated IR elements 104IR neck as the patterned stretchable tape 126P is stretched. In this embodiment, the patterned stretchable tape 126P may be periodically processed to allow additional stretching. For example, the patterned stretchable tape 126P may be heat treated in between periods of stretching.

FIGS. 11A-11G illustrates a process flow diagram for fabricating an electronic device, such as an optical device, e.g. a microLED display 100 or visible/SWIR sensor 300 according to another embodiment. As illustrated in FIG. 11A of this embodiment, an infrared wafer 102IR is provided on a stretchable tape 126. As in the embodiments described above, the stretchable tape 126 may be affixed to a tape frame carrier (not shown) for support. As illustrated in FIG. 11B, the infrared wafer 102IR may then be diced to form individual singulated IR elements 104IR. Next, as illustrated in FIG. 11C the stretchable tape 126 may be stretched to provide increased separation between the individual singulated IR elements 104IR. Then, as illustrated in FIG. 11D, a carrier wafer 101 may be provided. The carrier wafer 101 may be made of silicon or any other suitable material. In some embodiments carrier wafer 101 can be image sensor wafer (e.g. CMOS image sensor for optical wavelength to detect visible light) The carrier wafer 101 may be provided with cavities 128C configured to receive the individual singulated IR elements 104IR. Die on the wafer (no recessed portion of wafer 101) may fabricated to form optical image sensors. FIG. 11E is a plan view of the carrier wafer 101 illustrating the cavities 128 in two dimensions. In another embodiment, singulated die from another wafer (e.g. die from CMOS image sensor wafer 101) can be populated on another tape or a carrier. As illustrated in FIGS. 11F and 11G, the individual singulated IR elements 104IR may be transferred to and reconstituted on the carrier wafer 101 to form a visible/SWIR sensor 300. In an embodiment, the wafer carrier may include an integrated device element/die such as a processor element, e.g. a readout integrated circuit (ROIC). A Readout integrated circuit (ROIC) is an integrated circuit (IC) specifically used for reading detectors. The primary purpose for ROICs is to accumulate the photocurrent from each pixel and then transfer the resultant signal onto output taps for readout. In an alternative embodiment, the carrier wafer 101 does not include cavities 101C. In this embodiment, the individual singulated IR elements 104IR and separate readout integrated circuit elements can be bonded to the carrier wafer 101. Further, an insulating encapsulant layer 136 may be deposited over the individual singulated IR elements 104IR and the carrier wafer 101. The insulating encapsulant layer 136 may be an inorganic dielectric of one or multiple layers (e.g., silicon oxide, silicon nitride, etc.) or it may be an organic material, such as a molding compound. Further, the individual singulated IR elements 104IR may be directly bonded (e.g., hybrid bonded) to the carrier wafer 101.

FIGS. 12A-12E illustrates a process flow diagram for fabricating an electronic device, such as an optical device, e.g. a microLED display 100 or visible/SWIR sensor 300 according to another embodiment. As illustrated in FIG. 12A of this embodiment, an infrared wafer 102IR is provided on a stretchable tape 126. The stretchable tape 126 may be affixed to a tape frame carrier (not shown) for support. As illustrated in FIG. 12B, the infrared wafer 102IR may then be diced on the tape 126 to form individual singulated IR elements 104IR. Next, as illustrated in FIG. 12C the stretchable tape 126 may be stretched to provide increased separation between the individual singulated IR elements 104IR. As illustrated in FIG. 12D, a encapsulant 136 may be deposited over the individual singulated IR elements 104IR and the stretchable tape 126. In an embodiment, the encapsulant 136 may be transparent to visible light. In an embodiment, the encapsulant 136 may comprise silicon oxide. Further, in an embodiment, the encapsulant 136 may be thinned and bond pads 138 formed in the encapsulant 136. In an embodiment, the upper surface of the reconstituted element can comprise a direct bonding surface 1408b, including a nonconductive dielectric field region 1412b with embedded bond pads 138. The bonding surface 1408b may be prepared for hybrid bonding as explained above. In an alternative embodiment, the stretchable tape 126 may be removed and bond pads 138 formed on the bottom of the individual singulated IR elements 104IR. Indeed, a encapsulant 136 and bonding pads 138 may be formed on either the top side or the bottom side of the individual singulated IR elements 104IR in any of the embodiments described herein depending on the desired further processing of the microLED display 100 or visible/SWIR sensor 300.

FIG. 12E illustrates an embodiment in which singulated processing element 104P are direct (hydrid) bonded to the singulated IR elements 104IR. In an embodiment, encapsulant 136 is provided between the singulated processing dies 104P. In an embodiment, the singulated processing element 104P are provided on a temporary carrier (not shown) which may be removed. In alternative embodiments, the singulated processing element 104P may be provided on a carrier intended to be a part of the final device. In an embodiment, a redistribution layer (not shown) may be provided between the singulated IR elements 104IR and the singulated processing dies 104P. As shown, each singulated IR element 104IR has a corresponding singulated processing die 104P. However, a one to one ratio is not need. In embodiments, one or more singulated processing dies 104P may control more than one singulated IR element 104IR. Although die 104P is depicted to be positioned laterally above die 104IR in FIG. 12E, in another embodiment they may partially or completely offset as illustrated in FIG. 12F.

FIGS. 13A-13E illustrates a process flow diagram for fabricating a microLED display 100 according to another embodiment. As illustrated in FIG. 13A individual red wafers 102R, blue wafers 102B and green wafers 102G are affixed to separate stretchable tapes 126. As illustrated in FIG. 13B, the individual red wafers 102R, blue wafers 102B and green wafers 102G are diced to form individual red singulated elements 104R, green singulated elements 104G and blue singulated elements 104B. Then, as illustrated in FIG. 13D, the separate stretchable tapes 126 are stretched to increase the separation between the individual red singulated elements 104R, green singulated elements 104G and blue singulated elements 104B on their respective stretchable tapes 126. Then, as illustrated in FIG. 13E, the individual red singulated elements 104R, green singulated elements 104G and blue singulated elements 104B may be reconstituted on a carrier wafer 101 to form a microLED display 100. That is, the individual red singulated elements 104R, green singulated elements 104G and blue singulated elements 104B are attached to the substrate/carrier wafer 101 then encapsulated with an encapsulant layer 136. In another embodiment, the individual red singulated elements 104R, green singulated elements 104G and blue singulated elements 104B are reconstituted on one of the stretchable tapes 126 of individual red wafers 102R, blue wafers 102B and green wafers 102G and then the reconstituted wafer is bonded to the substrate/carrier wafer 101.

### EXAMPLES

Example 1. A method of transferring a plurality of singulated elements comprising:
providing a plurality of singulated elements on a stretchable tape;
stretching the stretchable tape to increase separation between the singulated elements; and
forming a reconstituted wafer with at least one of the plurality of elements.

Example 2. The method of Example 1, wherein forming a reconstituted wafer comprises testing the singulated elements and only using known good elements.

Example 3. The method of Example 1, wherein dicing comprises plasma etching, laser ablation or sawing.

Example 4. The method of Example 1, wherein the stretchable tape is stretched at least 50% relative to an unstretched area of the stretchable tape.

Example 5. The method of Example 1, wherein the reconstituted wafer is formed on the stretchable tape.

Example 6. The method of Example 5, further comprising coating the stretchable tape and the plurality of singulated elements with a transparent dielectric material.

Example 7. The method of Example 6, further comprising thinning the transparent dielectric material and forming bond pads on the elements.

Example 8. The method of Example 7, wherein the bond pads are prepared for hybrid bonding.

Example 9. The method of Example 1, wherein the reconstituted wafer is formed on a second carrier, different from the stretchable tape.

Example 10. The method of Example 9, wherein the at least first semiconductor wafer comprises a semiconductor material with a band gap suitable for short wavelength infrared sensors (SWIR) and the second carrier comprises a readout integrated circuit (ROIC) wafer.

Example 11. The method of Example 10, wherein the plurality of singulated elements are transferred to cavities in the second carrier wafer.

Example 12. The method of Example 1, wherein the at least first semiconductor wafer comprises a semiconductor material with a band gap suitable for light emitting diodes (LED).

Example 13. The method of Example 12, further comprising:
affixing at least a second semiconductor wafer to a second stretchable tape;
dicing the at least second semiconductor wafer to form a plurality of second singulated elements;
stretching the second stretchable tape to increase separation between the second singulated elements; and
forming a reconstituted wafer with at least one of the plurality of second singulated elements,
wherein the second semiconductor wafer comprise a semiconductor material with a band gap suitable for light emitting diodes different from the first semiconductor wafer.

Example 14. The method of claim 13, further comprising:
affixing at least a third semiconductor wafer to a third stretchable tape;
dicing the at least third semiconductor wafer to form a plurality of third singulated elements;
stretching the third stretchable tape to increase separation between the third singulated elements; and
forming a reconstituted wafer with at least one of the plurality of third singulated elements,
wherein the third semiconductor wafer comprises a semiconductor material with a band gap suitable for light emitting diodes different from the first and second semiconductor wafers.

Example 15. The method of Example 14, wherein the first, second and third elements are transferred to a fourth carrier to form a microLED panel.

Example 16. The method of Example 1, wherein stretching the stretchable tape comprises unfolding pre-folded portions of the stretchable tape.

Example 17. The method of Example 1, wherein stretching the stretchable tape comprises forming a patterned stretchable tape.

Example 18. The method of Example 1, further comprises periodically processing the stretchable tape to allow increased stretching.

Example 19. The method of Example 18, wherein periodically processing the stretchable tape comprises heating the stretchable tape.

Example 20. The method of Example 1, further comprising:
affixing at least a second semiconductor wafer to a second stretchable tape;
dicing the at least second semiconductor wafer to form a plurality of second singulated elements; and
forming a reconstituted wafer with at least a portion of the first plurality of singulated elements and plurality of second singulated elements,
wherein the first at least semiconductor wafer comprises a semiconductor material with a band gap suitable for short wavelength infrared sensors (SWIR) or a semiconductor material with a band gap suitable for light emitting diodes and wherein the reconstituted wafer is formed on a third carrier, different from the first stretchable tape and the second tape frame.

Example 21. The method of Example 20, wherein the third carrier comprises a silicon readout integrated circuit (ROIC) wafer.

Example 22. The method of Example 21, wherein the first and second stretchable tapes comprises pockets configured for die placement.

Example 23. The method of Example 1, wherein providing a plurality of individual elements singulated elements on a stretchable tape comprises:

affixing at least a first semiconductor wafer to a stretchable tape; and
dicing the at least first semiconductor wafer to form a plurality of individual elements.

Example 24. The method of Example 1, wherein forming a reconstituted wafer comprises coating the plurality of individual elements with an encapsulant.

Example 25. The method of Example 1, further comprising forming a bonding layer on the reconstituted wafer, the bonding layer comprising a bond pad and field regions extending between and partially or fully surrounding the bond pad.

Example 26. The method of Example 25 further comprising bonding a device to the reconstituted wafer.

Example 27. The method of Example 1, wherein forming a reconstituted wafer comprises simultaneously transferring multiple elements of the plurality of singulated elements to a carrier wafer.

Example 28. The method of Example 27, wherein the separation between elements after stretching the stretchable tape is the same as a desired spacing on the carrier wafer.

Example 29. A method of transferring a plurality of singulated elements comprising: providing a plurality of singulated elements on a stretchable tape comprising an array of adhesive pillars;
stretching the stretchable tape to increase separation between the singulated elements; and
forming a reconstituted wafer with at least a portion of the plurality of singulated elements.

Example 30. The method of Example 29, further comprising:

depositing an adhesive layer on a stretchable tape; and
patterning the adhesive layer to form an array of adhesive pillars on the stretchable tape.

Example 31. The method of Example 30, further comprising adhering singulated elements to the adhesive pillars or adhering at least a first semiconductor wafer to the array of adhesive pillars and dicing the at least first semiconductor wafer to form individual elements adhered to the adhesive pillars.

Example 32. The method of Example 29, further comprising depositing a release film on a temporary carrier and adhering the stretchable tape to the release film prior to patterning the adhesive layer.

Example 33. The method of Example 32, further comprising removing the release film, thereby separating the stretchable tape from the temporary carrier.

Example 34. The method of Example 33, wherein removing the release film comprises dissolving or ashing the release film.

Example 35. A method of transferring a plurality of singulated elements, the method comprising:
stretching a stretchable tape to increase a separation distance between adjacent singulated integrated device elements; and
providing an encapsulant over a carrier to which the singulated integrated device elements are affixed and at least partially embedding the singulated integrated device elements in the encapsulant.

Example 36. The method of Example 35, wherein the carrier is the stretchable tape or a separate carrier.

Example 37. The method of Example 35, further comprising forming a bonding layer comprising bond pads and field regions between the bond pads.

Example 38. The method of Example 37 wherein the bond layer may be used for direct hybrid bonding.

Example 39. The method of Example 35, further comprising simultaneously transferring multiple elements of the plurality of singulated elements to a carrier.

Example 40. The method of Example 336, wherein the separation distance between elements after stretching the stretchable tape is the same as a desired spacing on the carrier.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A method of transferring a plurality of singulated elements comprising:
providing a plurality of singulated elements on a stretchable tape;
stretching the stretchable tape to increase separation between the singulated elements; and
forming a reconstituted wafer with at least one of the plurality of elements.

2. The method of claim 1, wherein forming a reconstituted wafer comprises testing the singulated elements and only using known good elements.

3. The method of claim 1, wherein dicing comprises plasma etching, laser ablation or sawing.

4. The method of claim 1, wherein the stretchable tape is stretched at least 50% relative to an unstretched area of the stretchable tape.

5. The method of claim 1, wherein the reconstituted wafer is formed on the stretchable tape.

6. (canceled)

7. (canceled)

8. (canceled)

9. The method of claim 1, wherein the reconstituted wafer is formed on a second carrier, different from the stretchable tape.

10. (canceled)

11. (canceled)

12. The method of claim 1, wherein the at least first semiconductor wafer comprises a semiconductor material with a band gap suitable for light emitting diodes (LED).

13. (canceled)

14. (canceled)

15. (canceled)

16. The method of claim 1, wherein stretching the stretchable tape comprises unfolding pre-folded portions of the stretchable tape.

17. The method of claim 1, wherein stretching the stretchable tape comprises forming a patterned stretchable tape.

18. The method of claim 1, further comprises periodically processing the stretchable tape to allow increased stretching.

19. (canceled)

20. The method of claim 1, further comprising:
affixing at least a second semiconductor wafer to a second stretchable tape;
dicing the at least second semiconductor wafer to form a plurality of second singulated elements; and
forming a reconstituted wafer with at least a portion of the first plurality of singulated elements and plurality of second singulated elements,
wherein the first at least semiconductor wafer comprises a semiconductor material with a band gap suitable for short wavelength infrared sensors (SWIR) or a semiconductor material with a band gap suitable for light emitting diodes and wherein the reconstituted wafer is formed on a third carrier, different from the first stretchable tape and the second tape frame.

21. (canceled)

22. (canceled)

23. The method of claim 1, wherein providing a plurality of individual elements singulated elements on a stretchable tape comprises:
affixing at least a first semiconductor wafer to a stretchable tape; and
dicing the at least first semiconductor wafer to form a plurality of individual elements.

24. The method of claim 1, wherein forming a reconstituted wafer comprises at least partially embedding the plurality of individual elements in an encapsulant.

25. (canceled)

26. (canceled)

27. The method of claim 1, wherein forming a reconstituted wafer comprises simultaneously transferring multiple elements of the plurality of singulated elements to a carrier wafer.

28. (canceled)

29. A method of transferring a plurality of singulated elements comprising:
providing a plurality of singulated elements on a stretchable tape comprising an array of adhesive pillars;
stretching the stretchable tape to increase separation between the singulated elements; and
forming a reconstituted wafer with at least a portion of the plurality of singulated elements.

30. The method of claim 29, further comprising:
depositing an adhesive layer on a stretchable tape; and
patterning the adhesive layer to form an array of adhesive pillars on the stretchable tape.

31. (canceled)

32. (canceled)

33. (canceled)

34. (canceled)

35. stretching a stretchable tape having singulated integrated device elements thereon to increase a separation distance between adjacent singulated integrated device elements; and
providing an encapsulant over a carrier to which the singulated integrated device elements are affixed and at least partially embedding the singulated integrated device elements in the encapsulant.

36. The method of claim 35, wherein the carrier is the stretchable tape or a separate carrier.

37. The method of claim 35, further comprising forming a bonding layer comprising bond pads and field regions between the bond pads.

38. (canceled)

39. The method of claim 35, further comprising simultaneously transferring multiple elements of the plurality of singulated elements to a carrier.

40. (canceled)
